(19) United States
(12) Patent Application Publication
(10) Pub. No.: US 2026/0312307 A1
(43) Pub. Date: Oct. 8, 2026

(54) CONTAINER FOR SUPERCONDUCTING WIRE CONNECTION AND SUPERCONDUCTING MAGNET

(71) Applicant: CANON KABUSHIKI KAISHA, Tokyo (JP)

(72) Inventors: Takehiro SHIBUYA, Nasushiobara Tochigi (JP); Michiru KAJIWARA, Nasushiobara Tochigi (JP); Hiromi KAWAMOTO, Yaita Tochigi (JP); Sadanori TOMIHA, Nasushiobara Tochigi (JP); Katsutoshi MIZUNO, Nasushiobara Tochigi (JP)

(73) Assignee: CANON KABUSHIKI KAISHA, Tokyo (JP)

(21) Appl. No.: 19/273,557

(22) Filed: Jul. 18, 2025

(30) Foreign Application Priority Data
Jul. 19, 2024 (JP) 2024-115553

(51) Int. Cl. H01R 4/68; G01R 33/3815; H01B 12/10; H01B 12/16; H01R 4/02

(52) U.S. Cl. CPC H01R 4/68; H01B 12/10; H01B 12/16; H01R 4/021; G01R 33/3815; H01R 2201/12

(57) ABSTRACT

A container for superconducting wire connection according to an embodiment includes a superconducting wire material, a superconducting solder, a container, and an inner wall. The superconducting wire material includes a superconducting material. The superconducting solder is used to electrically bond two or more of the superconducting wire materials. The container includes an outer wall and a bottom plate to hold the superconducting solder and the superconducting wire materials. The inner wall is at least partially integrated with the bottom plate so that a cavity is provided in the container.

### CROSS-REFERENCE TO RELATED APPLICATIONS

This application is based upon and claims the benefit of priority from Japanese Patent Application No. 2024-115553, filed on Jul. 19, 2024; the entire contents of which are incorporated herein by reference.

### FIELD

Embodiments described herein relate generally to a container for superconducting wire connection and a superconducting magnet.

### BACKGROUND

Some magnetic resonance imaging (MRI) devices use superconducting magnets including superconductors. For forming the superconducting magnet, connection between superconducting wires is important. In the connection between the superconducting wires, it is important to suppress power loss.

Here, in one method for connecting the superconducting wires, the superconducting wires are soldered together using a superconducting solder that exhibits superconductivity at low temperature, the soldered superconducting wires are sealed in a container to form a container for superconducting wire connection, and the superconducting wires are connected using the container for superconducting wire connection.

However, when the superconducting solder is cooled and solidified in the container, voids may be generated, and if voids are formed near the superconducting wire, the connection characteristic of the superconducting wire may deteriorate.

### BRIEF DESCRIPTION OF THE DRAWINGS

FIG. 1 is a diagram describing one example of the procedure for forming a container for superconducting wire connection;

FIG. 2 is a diagram describing one example of the procedure for forming the container for superconducting wire connection;

FIG. 3 is a diagram describing the background related to an embodiment;

FIG. 4 is a diagram describing an appearance of a container for superconducting wire connection according to a first embodiment;

FIG. 5 is a cross-sectional view describing a configuration of the container for superconducting wire connection according to the first embodiment;

FIG. 6 is a diagram describing one example of a configuration of a container for superconducting wire connection according to a second embodiment;

FIG. 7 is a diagram describing one example of the configuration of the container for superconducting wire connection according to the second embodiment;

FIG. 8 is a diagram describing one example of the configuration of the container for superconducting wire connection according to the second embodiment; and

FIG. 9 is a diagram describing one example of the configuration of the container for superconducting wire connection according to the second embodiment.

FIG. 10 is a diagram describing one example of the configuration of the container for superconducting wire connection according to the second embodiment.

### DETAILED DESCRIPTION

A container for superconducting wire connection provided in an aspect of an embodiment includes a superconducting wire material, a superconducting solder, a container, and an inner wall. The superconducting wire material includes a superconducting material. The superconducting solder is used to electrically bond two or more of the superconducting wire materials. The container includes an outer wall and a bottom plate to hold the superconducting solder and the superconducting wire materials. The inner wall is at least partially integrated with the bottom plate so that a cavity is provided in the container.

### First Embodiment

With reference to drawings, embodiments of a superconducting wire connection container and a superconducting magnet will be described below in detail.

First, the connection of superconducting wire materials is described. For example, superconducting magnets including superconductors are used in magnetic resonance imaging (MRI) devices, and the connection between the superconducting wires is important for forming the superconducting magnets. In the connection between the superconducting wires, it is important to suppress power loss.

In one method for connecting between the superconducting wires, the superconducting wires are soldered using a superconducting solder that exhibits superconductivity at low temperature, and the soldered superconducting wires are sealed in a container to form a container for superconducting wire connection. Through this container for superconducting wire connection, the superconducting wires are connected to each other and thus, for example, a superconducting magnet for MRI can be generated.

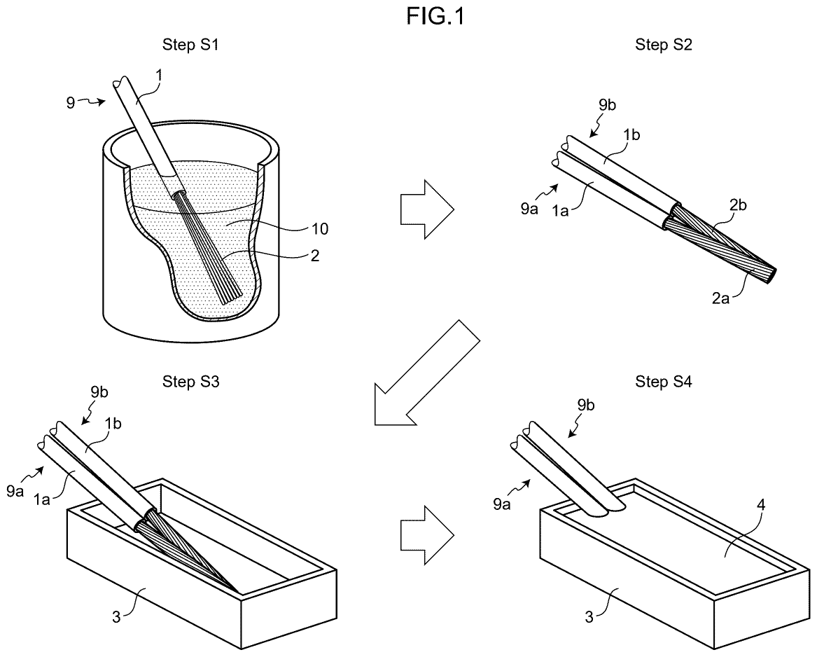

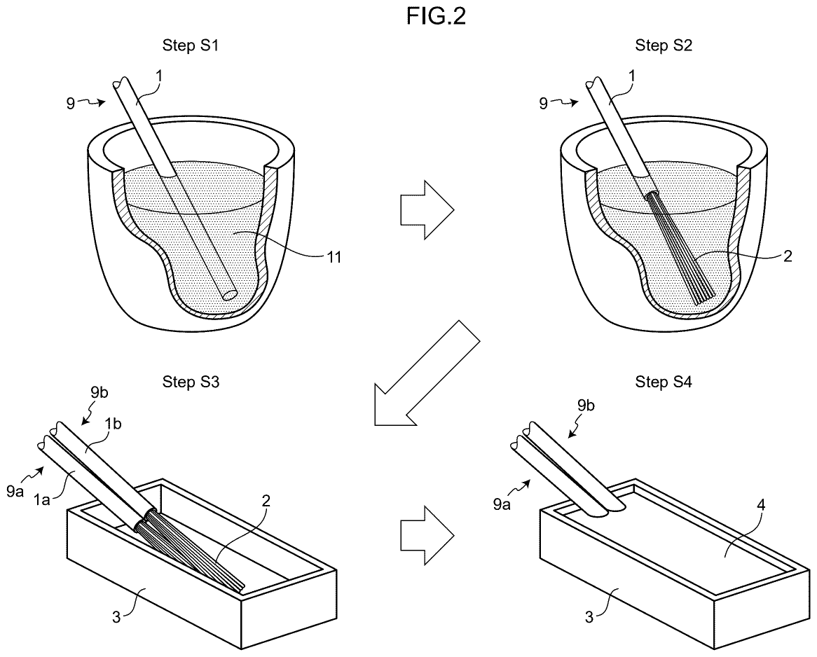

FIG. 1 and FIG. 2 illustrate examples of the procedure for forming the container for superconducting wire connection. FIG. 1 illustrates an example in a case of forming the container for superconducting wire connection by a method of soldering filaments of the superconducting wire materials after immersed in concentrated nitric acid, and FIG. 2 illustrates an example in a case of forming the container for superconducting wire connection by a method of soldering the superconducting wire materials after tin substitution.

FIG. 1 illustrates the example in the case in which the container for superconducting wire connection is formed by the method of soldering the filaments of the superconducting wire materials after immersed in concentrated nitric acid. First, at step S1, a superconducting wire material 9 typically includes a base material 1 containing copper or a copper compound, and a superconducting material 2 provided inside the base material 1. For example, NbTi, Nb₃Sn, or the like is used as the superconducting material 2. When the superconducting wire material 9 is immersed in concentrated nitric acid 10, the base material 1, which is formed of copper or the copper compound, dissolves, so that the superconducting material 2 therein is exposed and forms a filament shape.

Subsequently, at step S2, the two filaments in the parts of the superconducting materials 2 thus exposed in this way are twisted together. Specifically, a superconducting material 2a with a filament shape in a superconducting wire material 9a formed of a base material 1a and the superconducting material 2a, and a superconducting material 2b with a filament shape in a superconducting wire material 9b formed of a base material 1b and the superconducting material 2b are twisted together; thus, the superconducting wire material 9a and the superconducting wire material 9b are connected to each other.

Subsequently, at step S3, the superconducting wire material 9a and the superconducting wire material 9b are placed in a container 3. The container 3 is typically made of a conductive material such as copper.

Then, at step S4, two or more superconducting wire materials, that is, the superconducting wire material 9a and the superconducting wire material 9b are electrically bonded to each other by a superconducting solder 4. The superconducting solder 4 is a solder that exhibits superconductivity at low temperature. In one example, the superconducting wire material 9a and the superconducting wire material 9b are soldered together by the solder as the superconducting solder 4, which is in a liquid state at high temperature (exhibiting a superconducting state at low temperature), and the superconducting solder 4 solidifies at low temperature. Thus, the superconducting wire material 9a and the superconducting wire material 9b are electrically bonded to each other by the superconducting solder 4. In the low-temperature state after further cooling to, for example, liquid helium temperature, the superconducting solder 4 becomes the superconducting state, so that the electrical resistance of a connection part between the superconducting wire material 9a and the superconducting wire material 9b becomes zero and power loss is suppressed.

FIG. 2 illustrates an example in a case of forming the container for superconducting wire connection by the method of soldering the filaments of the superconducting wire materials 9 after the tin substitution. First, at step S1, the superconducting wire material 9 typically includes the base material 1 containing copper or the copper compound, and the superconducting material provided inside the base material 1. For example, NbTi, Nb₃Sn, or the like is used as the superconducting material. When the superconducting wire material 9 is immersed into molten tin 11, the base material 1 formed of copper or the copper compound dissolves and the superconducting material 2 is exposed, as can be seen at step S2. At this time, a surface of the superconducting material 2 is coated with tin. Accordingly, tin plating is performed. Such an operation is performed for each of the two superconducting wire materials.

Subsequently, at step S3, the tin-plated superconducting wire materials 9a and 9b are placed in the container 3. The container 3 is typically made of a conductive material such as copper.

Then, at step S4, two or more superconducting wire materials, that is, the superconducting wire material 9a and the superconducting wire material 9b are electrically bonded to each other by the superconducting solder 4. Specifically, the superconducting solder 4 is a solder that exhibits superconductivity at low temperature, for example. In one example, the superconducting wire material 9a and the superconducting wire material 9b are soldered together by the solder as the superconducting solder 4, which is in a liquid state at high temperature (exhibiting a superconducting state at low temperature), and the superconducting solder 4 solidifies at low temperature. Thus, the superconducting wire material 9a and the superconducting wire material 9b are electrically bonded to each other by the superconducting solder 4. In the low-temperature state after further cooling to, for example, liquid helium temperature, the superconducting solder 4 becomes the superconducting state, so that the electrical resistance of a connection part between the superconducting wire material 9a and the superconducting wire material 9b becomes zero and power loss is suppressed.

In the aforementioned method for forming the container for superconducting wire connection for the connection of the superconducting wires, the container for superconducting wire connection is formed by the method of soldering the filaments after the immersion in the concentrated nitric acid or the container for superconducting wire connection is formed by the method of soldering the superconducting wire materials after the tin substitution. However, the embodiment is not limited to this example, and in the embodiment, the superconducting wires may be connected by crimp bonding, solid-phase bonding, or the like.

Here, the crimp bonding means a method of bonding a plurality of superconducting wire materials by crimping. In the case of the crimp bonding, first, steps S1 and S2 in FIG. 1 are performed similarly. In the case of the crimp bonding, the superconducting wire material 9a and the superconducting wire material 9b are inserted into a metal sleeve at step S3. At step S4, the superconducting wire material 9a and the superconducting wire material 9b are bonded together by crimping with pressure applied by the metal sleeve. Finally, the vicinity of an entrance of the metal sleeve is soldered.

In the case of the solid-phase bonding, steps S1 and S2 in FIG. 1 are performed similarly. In the case of the solid-phase bonding, the superconducting wire material 9a and the superconducting wire material 9b are inserted into a compression jig at step S3. At step S4, the compression jig is pressurized and heated to perform the solid-phase bonding of the superconducting wire material 9a and the superconducting wire material 9b.

Subsequently, the background of the embodiment will be described.

The formation of the container for superconducting wire connection has been described so far. In the case where the superconducting solder 4, which is in a liquid state, is cooled and solidified in the container 3 at step S4, voids or gaps may be generated.

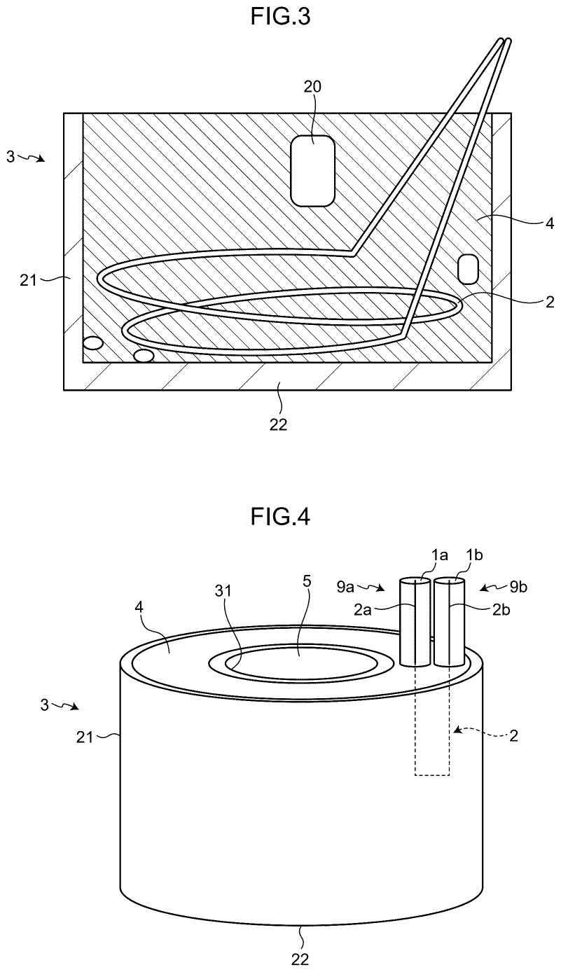

This point will be described with reference to FIG. 3. FIG. 3 is a diagram illustrating a structure of the container 3, which is a container for superconducting wire connection according to a comparative example. The container 3 includes an outer wall 21 and a bottom plate 22 to hold the superconducting material 2 and the superconducting solder 4. The superconducting solder 4 is a solder with a superconducting property at low temperature. Here, when the superconducting solder is cooled and solidified in the container, a void 20 may be generated. Here, if the void 20 is generated near the superconducting material 2, the connection characteristic of the superconducting wire may deteriorate. Therefore, it is desirable that control be exercised so that the void 20 is not generated near the superconducting material 2.

In view of such a circumstance, the container for superconducting wire connection according to the embodiment includes the superconducting wire material including the superconducting material 2; the superconducting solder 4 used for electrically bonding two or more superconducting wire materials; and the container 3 including the outer wall 21 and the bottom plate 22 to hold the superconducting solder 4 and the superconducting wire material. The container 3 includes an inner wall that is at least partially integrated with the bottom plate 22 so that a cavity is provided. Specifically, the container 3 includes the inner wall that is at least partially integrated with the bottom plate 22 so that the cavity is provided from the bottom plate part.

Here, the cavity is provided from the bottom plate part of the container 3, so that a difference is produced in cooling rate between the inner wall and the outer wall; thus, the void generation can be controlled. This point will be discussed later. In addition, the structure provided with the cavity makes it possible to efficiently cool the container 3 when, for example, the container is incorporated and operated as a part of a superconducting magnet.

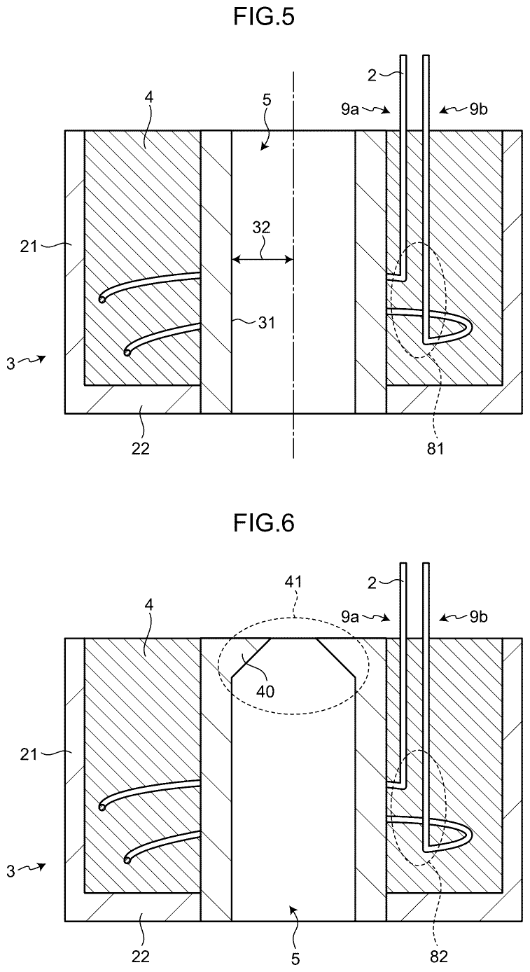

The configuration according to the first embodiment will be described in detail with reference to FIG. 4 and FIG. 5. FIG. 4 is an external view of the container for superconducting wire connection according to the first embodiment, and FIG. 5 is a cross-sectional view of the container for superconducting wire connection according to the first embodiment.

As illustrated in FIG. 4 and FIG. 5, the container for superconducting wire connection according to the embodiment includes the superconducting wire materials 9a and 9b including the superconducting materials 2a and 2b, the superconducting solder 4 used to electrically bond two or more of the superconducting wire materials 9a and 9b, and the container 3 including the outer wall 21 and the bottom plate 22 to hold the superconducting solder 4 and the superconducting wire materials 9a and 9b. Here, the superconducting wire materials 9a and 9b include the base materials 1a and 1b containing copper or the copper compound, and the superconducting materials 2a and 2b provided inside the base materials 1a and 1b. The superconducting solder 4 is, for example, a solder that exhibits superconductivity at low temperature. The superconducting wire materials included in the superconducting coil of the superconducting magnet, for example, are connected to each other using the container for superconducting wire connection according to the embodiment.

Here, the cavity 5 is provided from the bottom plate part of the container 3. The container 3 includes an inner wall 31 that is at least partially integrated with the bottom plate 22. Note that the container for superconducting wire connection according to the embodiment includes, in addition to the container 3, the superconducting wire materials 9a and 9b that are placed in the container 3 and the superconducting solder 4 that fills the container 3.

The inner wall 31 may be formed of a conductive material to enhance thermal conductivity.

Next, the effect that can be obtained by using the container for superconducting wire connection according to the embodiment will be described. The container 3 according to the embodiment includes the cavity 5, so that a difference can be produced in cooling rate between the inner wall 31 and the outer wall 21. In one example, the inner wall 31 and the outer wall 21 can be designed so that the cooling rate near the inner wall 31 becomes higher than the cooling rate near the outer wall 21.

Here, it is known that there is a negative correlation between the cooling rate in cooling and solidifying the superconducting solder 4 and the number of voids generated. In other words, when the superconducting solder 4 is cooled and solidified rapidly, fewer voids are generated than when the superconducting solder 4 is cooled and solidified slowly. The probability of void generation is smaller at locations where the superconducting solder 4 is cooled and solidified rapidly than at locations where the superconducting solder 4 is cooled and solidified slowly. Thus, void generation can be controlled.

In one example, in the container for superconducting wire connection according to the embodiment, the temperature decrease rate in cooling can be made different depending on the location by making the structure of the wall depending on the location. In one example, by making the thickness of the inner wall 31 different from the thickness of the outer wall 21, the temperature decrease rate can be varied. In another example, the material of the inner wall 31 is made different from that of the outer wall 21, thereby making thermal conductivity different and thus making the temperature decrease rate in cooling different.

Here, the superconducting wire materials 9a and 9b are provided at the locations where the temperature decrease rate in cooling is high.

In one example, if the cooling rate near the inner wall 31 is designed to be higher than that near the outer wall 21, the probability of void generation near the inner wall 31 is smaller than that near the outer wall 21. Therefore, the superconducting wire materials 9a and 9b are provided near the inner wall 31, where the temperature decrease rate in cooling is high. In this case, when the superconducting wire materials 9a and 9b are placed near the inner wall 31, the probability of void generation is lower in a region 81 where the superconducting wire materials 9a and 9b are placed than in the other regions. As a result, the probability of void generation in the region where the superconducting wire materials 9a and 9b are placed can be made lower than the probability of void generation in the other regions, and the connection characteristic of the superconducting wires can be improved.

In contrast to the case described above, if the cooling rate near the inner wall 31 is designed to be lower than that near the outer wall 21, the probability of void generation near the inner wall 31 becomes higher than that near the outer wall 21. In this case, the superconducting wire materials 9a and 9b are provided near the outer wall 21, where the temperature decrease rate in cooling is high. Even in this case, the probability of void generation in the region where the superconducting wire materials 9a and 9b are placed can be made lower than the probability of void generation in the other regions, and the connection characteristic of the superconducting wires can be improved.

Back to the description of the embodiment, another effect obtained by using the container for superconducting wire connection according the embodiment is that the cooling efficiency is improved because the container 3 according to the embodiment includes the cavity 5 in the central part. Specifically, the region near the inner wall 31 can be cooled in a short time compared to the case in which the cavity 5 does not exist. The container for superconducting wire connection according to the embodiment is used in such a way that the superconducting solder 4 is cooled to the temperature at which the superconducting solder 4 becomes superconductive, and makes the cooling of the container 3 at this time more efficient. When the inner wall 31 is formed of the conductive material, thermal conductivity of the inner wall 31 can be enhanced and furthermore, the cooling rate of the container 3 can be improved.

The embodiment is not limited to the above examples. In another example, the cooling rate can be controlled by controlling a diameter 32 of the cavity 5. Specifically, by increasing the diameter 32 of the cavity 5, the surface area in contact with the air and a thermal conductor near the inner wall 31 can be increased, thereby increasing the cooling rate. This allows the location of the void concentration to be somewhere other than near the inner wall 31. Thus, void generation can be controlled. The cooling rate near the inner wall 31 can be controlled by changing the size and shape of the cavity 5 and the thickness, angle, and shape of the inner wall 31, and based on this, the probability of void generation can be controlled. The cross-sectional shape of the cavity 5 (inner wall 31) may be a circle, an ellipse, a triangle, a quadrangle, a polygon, or any other shape. The cross-sectional shape of the outer wall 21 and the bottom plate 22 may also be a circle, an ellipse, a triangle, a quadrangle, a polygon, or various other shapes.

The embodiment is not limited to the above example, and the cooling efficiency near the inner wall 31 may be further enhanced by filling the cavity 5 with the thermal conductor.

In the embodiment illustrated in FIG. 4 and FIG. 5, the connection method for the superconducting wire materials is described regarding the case illustrated in FIG. 1 where the superconducting wire materials are immersed in concentrated nitric acid and then bonded together with the superconducting solder 4 and the case illustrated in FIG. 2 where tin plating is used. However, the connection method for the superconducting wire materials is not limited to these cases, and in another example, the superconducting wire materials may be connected using the crimp bonding or the solid-phase bonding.

In the first embodiment described above, the container for superconducting wire connection includes the superconducting wire material including the superconducting material 2, the superconducting solder 4 used for electrically bonding two or more superconducting wire materials, and the container 3 including the outer wall 21 and the bottom plate 22 to hold the superconducting solder 4 and the superconducting wire materials, in which the container 3 includes the inner wall that is at least partially integrated with the bottom plate 22 so that the cavity 5 is provided from the bottom plate part of the container 3. Providing the cavity 5 from the bottom plate part of the container 3 makes it possible to control the void generation. In addition, cooling efficiency of the container 3 can be increased.

### Second Embodiment

The embodiment is not limited to the above examples. A second embodiment will describe a case in which the shape of the inner wall 31 is changed variously.

In one example, as illustrated in FIG. 6, a container for superconducting wire connection according to the second embodiment includes the superconducting wire materials 9a and 9b, the superconducting solder 4 used to electrically bond the two or more superconducting wire materials 9a and 9b, and the container 3 including the outer wall 21 and the bottom plate 22 to hold the superconducting solder 4 and the superconducting wire materials 9a and 9b. Here, the cavity 5 is provided from the bottom plate part of the container 3, and the container 3 includes an inner wall 40 that is at least partially integrated with the bottom plate 22. However, the wall thickness of a region 41 corresponding to an upper part of the inner wall 40 (the part away from the bottom plate 22) is made larger than that of a part of the inner wall 40 that is closer to the bottom plate 22. In other words, the thickness of the inner wall 40 and the outer wall 21 is different depending on the height designed from the bottom plate 22. Accordingly, the cooling rate near the bottom plate 22 of the inner wall 40 becomes higher than the cooling rate near the upper part of the inner wall 40. Thus, for example, the probability of void generation in a vicinity of a region 82 becomes smaller, and the effect of voids can be reduced by placing the superconducting wire material in the vicinity of the region 82.

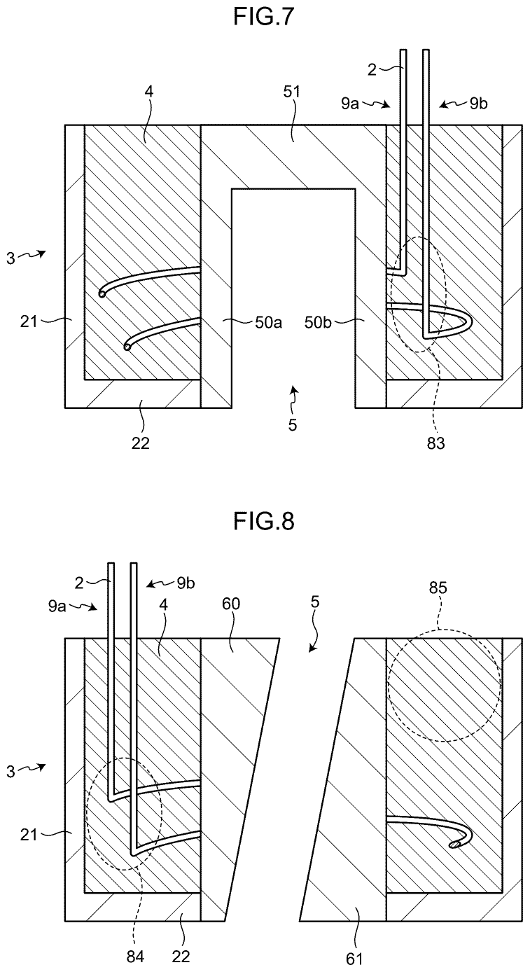

In another embodiment, as illustrated in FIG. 7, a container for superconducting wire connection according to the embodiment includes the superconducting wire materials 9a and 9b, the superconducting solder 4 used to electrically bond the two or more superconducting wire materials 9a and 9b, and the container 3 including the outer wall 21 and the bottom plate 22 to hold the superconducting solder 4 and the superconducting wire materials 9a and 9b, inner walls 50a and 50b, and a wall 51. Here, the cavity 5 is provided from the bottom plate part of the container 3, with an upper part of the cavity 5 covered with the wall 51. In other words, the wall 51 connecting the inner walls 50a and 50b to each other is provided on a side in the inner walls 50a and 50b opposite to the bottom plate 22. Thus, the cooling rate near the bottom plate 22 of the inner walls 50a and 50b becomes higher than the cooling rate near an upper part of the inner walls 50a and 50b. Thus, for example, the probability of void generation in a vicinity of a region 83 becomes smaller, and the effect of voids can be reduced by placing the superconducting wire material in the vicinity of the region 83.

In another embodiment, as illustrated in FIG. 8, a container for superconducting wire connection according to the embodiment includes the superconducting wire materials 9a and 9b, the superconducting solder 4 used to electrically bond the two or more superconducting wire materials 9a and 9b, and the container 3 including the outer wall 21 and the bottom plate 22 to hold the superconducting solder 4 and the superconducting wire materials 9a and 9b, and inner walls 60 and 61 installed oblique to the bottom plate. Thus, the cooling rate near regions 84 and 85, for example, becomes higher than the cooling rate in the other regions. Thus, for example, the probability of void generation in vicinities of the regions 84 and 85 becomes smaller, and the effect of voids can be reduced by placing the superconducting wire material in the vicinities of the regions 84 and 85.

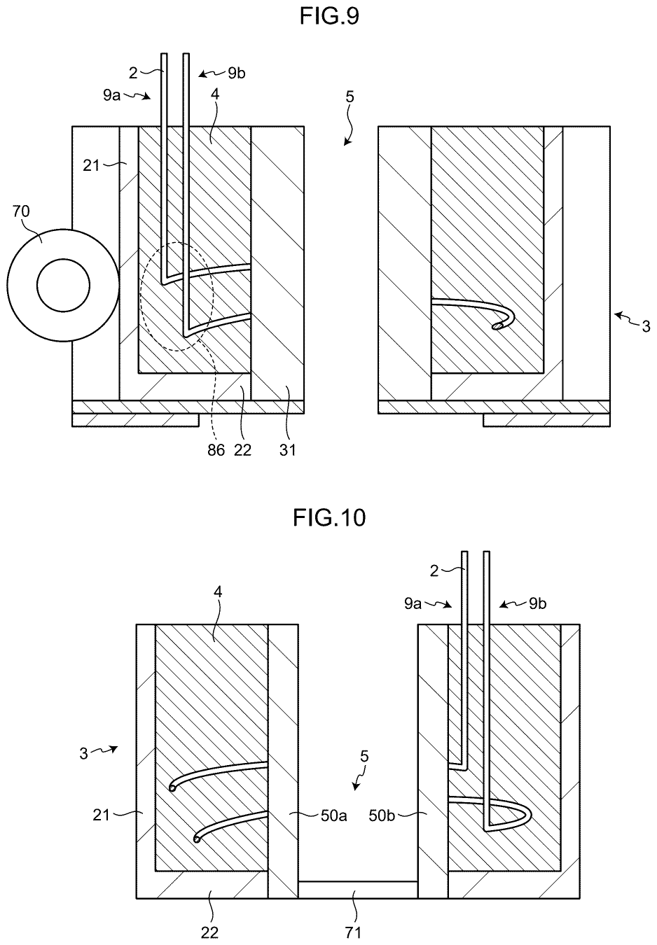

In another embodiment, as illustrated in FIG. 9, a container for superconducting wire connection according to the embodiment includes the superconducting wire materials 9a and 9b, the superconducting solder 4 used to electrically bond the two or more superconducting wire materials 9a and 9b, and the container 3 including the outer wall 21 and the bottom plate 22 to hold the superconducting solder 4 and the superconducting wire materials 9a and 9b, and the inner wall 31. Here, a thermal conductor 70 or the like for cooling is further provided. Thus, the cooling rate near a region 86, for example, becomes higher than the cooling rate in the other regions. Thus, for example, the probability of void generation in a vicinity of a region 86 becomes smaller, and the effect of voids can be reduced by placing the superconducting wire material in the vicinity of the region 86.

As another embodiment, unlike the embodiment shown in FIG. 7, in which the upper part of the cavity 5 is blocked by a wall 51, for example, as shown in FIG. 10, the lower part of the cavity 5 may be blocked by the bottom plate 71 and the bottom plate 71 and the bottom plate 22 may form the bottom plate of the container for superconducting wire connection. In this case, the bottom plate is formed inside the inner walls 50a, 50b and includes a portion that blocks the lower part of the cavity 5. That is, the superconducting wire connection wire container according to the embodiment includes the superconducting wire materials 9a and 9b, a superconducting solder 4 used for electrically joining two or more superconducting wire materials 9a, 9b, and an outer wall 21 and a bottom plate 22 that hold the superconducting solder 4 and the superconducting wire materials 9a and 9b, and a container 3 having a bottom plate 71 formed inside the inner walls 50a and 50b and blocking the lower part of the cavity 5. In this embodiment, it is possible to design an area of the bottom plate to be large, and it is possible to efficiently cool the container for connecting the container for superconducting wire connection.

According to at least one of the embodiments described above, the void generation can be reduced in the container for superconducting wire connection.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A container for superconducting wire connection comprising:
a superconducting wire material including a superconducting material;
a superconducting solder used to electrically bond two or more of the superconducting materials;
a container including an outer wall and a bottom plate to hold the superconducting solder and the superconducting wire materials; and
an inner wall at least partially integrated with the bottom plate so that a cavity is provided in the container.

2. The container for superconducting wire connection according to claim 1, wherein the inner wall is formed of a conductive material.

3. The container for superconducting wire connection according to claim 1, wherein a temperature decrease rate in cooling is made different depending on a location by making a structure of a wall different depending on the location.

4. The container for superconducting wire connection according to claim 1, wherein a thickness of the inner wall is different from a thickness of the outer wall.

5. The container for superconducting wire connection according to claim 3, wherein the superconducting wire materials are provided at a location where the temperature decrease rate is high.

6. The container for superconducting wire connection according to claim 1, wherein a thickness of the inner wall and the outer wall is different depending on a height designed from the bottom plate.

7. The container for superconducting wire connection according to claim 1, wherein a wall connecting the inner wall to another inner wall is provided on a side in the inner wall opposite to the bottom plate.

8. The container for superconducting wire connection according to claim 1, further comprising a thermal conductor for cooling.

9. The container for superconducting wire connection according to claim 1, wherein the superconducting wire material includes a base material containing copper or a copper compound, and the superconducting material provided inside the base material.

10. The container for superconducting wire connection according to claim 1, wherein the bottom plate includes a portion that is formed inside the inner wall and that blocks a lower portion of the cavity.

11. A superconducting magnet wherein a superconducting wire material included in a superconducting coil is connected using the container for superconducting wire connection according to claim 1.
